(19) United States
(12) Patent Application Publication
(10) Pub. No.: US 2026/0106574 A1
(43) Pub. Date: Apr. 16, 2026

(54) POWER AMPLIFIER FOR REDUCED LOAD PULL RATIO

(71) Applicant: HUAWEI TECHNOLOGIES CO., LTD., Shenzhen (CN)

(72) Inventors: Song Li, Chengdu (CN); Francesc Purroy Martin, Kista (SE); Ruiming Mo, Shanghai (CN)

(73) Assignee: HUAWEI TECHNOLOGIES CO., LTD., Shenzhen (CN)

(21) Appl. No.: 19/387,093

(22) Filed: Nov. 12, 2025

Related U.S. Application Data
(63) Continuation of application No. PCT/EP2023/064636, filed on Jun. 1, 2023.

(51) Int. Cl. H03F 1/02; H01P 1/38; H03F 1/56; H03F 3/24

(52) U.S. Cl. CPC H03F 1/0288; H01P 1/38; H03F 1/56; H03F 3/245; H03F 2200/102; H03F 2200/451

(57) ABSTRACT

A power amplifier includes at least three amplifiers which receive a first signal, a second signal, and a third signal, respectively. Each of the amplifiers output an amplified signal that includes an amplified version of their respective received signal. The power amplifier further includes a circulator that includes an input port, an output port, and an isolated port. The input port is connected to the output of the first amplifier and the output of the second amplifier and is configured to receive the first amplified signal and the second amplified signal and provide the first amplified signal and the second amplified signal to a load via the output port. The isolated port is connected to the output of the third amplifier and is configured to receive the third amplified signal and provide the third amplified signal to the load via the output port.

### CROSS-REFERENCE TO RELATED APPLICATIONS

This application is a continuation of International Application No. PCT/EP2023/064636, filed on Jun. 1, 2023, the disclosure of which is hereby incorporated by reference in its entirety.

### FIELD

Embodiments of the present disclosure relate to a power amplifier for reduced load pull ratio, and a transmitter device for a communication system comprising such a power amplifier.

### BACKGROUND

Power amplifiers (PAs) are important components in base stations for mobile communications. Increasing demand for large capacity in wireless communication systems, such as in 3GPP new radio (NR), requires power amplifiers (PA) that e.g., can handle broad bandwidth signals and high peak-to-average power ratios (PAPR).

In communication networks, the probability of running at heavy traffic loads is low and base stations of communication networks usually work at light traffic loads. Thus, energy-efficient power amplifiers with high efficiency both at large back-off and nominal power can substantially reduce the energy consumption of base station radio units.

### SUMMARY

Embodiments of the present disclosure provide a power amplifier solution for reduced load pull ratio.

According to a first aspect of the present disclosure, a power amplifier comprises:
an input block configured to receive at least one input signal and provide a first signal, a second signal, and least one third signal based on the input signal;
a first amplifier comprising: an input connected to the input block and configured to receive the first signal, and an output configured to output a first amplified signal comprising an amplified version of the first signal;
a second amplifier comprising: an input connected to the input block and configured to receive the second signal, and an output configured to output a second amplified signal comprising an amplified version of the second signal;
a third amplifier comprising: an input connected to the input block and configured to receive the third signal, and an output configured to output a third amplified signal comprising an amplified version of the third signal; and
a circulator comprising: an input port connected to the output of the first amplifier and the output of the second amplifier and configured to receive the first amplified signal and the second amplified signal and provide the first amplified signal and the second amplified signal to a load via an output port of the circulator, and an isolated port connected to the output of the third amplifier and configured to receive the third amplified signal and provide the third amplified signal to the load via the output port of the circulator.

An advantage of the power amplifier according to the first aspect is that reduced load pull ratio is possible compared to conventional solutions. Further, larger back off, wider bandwidth, and lower insertion losses are also possible compared to conventional solutions. Moreover, smaller number of devices and thus more compact power amplifier circuits may be provided.

In an implementation form of a power amplifier according to the first aspect, the first amplifier comprises a main amplifier.

In an implementation form of a power amplifier according to the first aspect, the main amplifier is any one of: a single-ended amplifier, a multi-stage Doherty amplifier, a hybrid Doherty amplifier, a circulator load modulated amplifier (CLMA), an inverted CLMA, a load-modulated balanced amplifier (LMBA), a distributed LMBA, an envelope tracking amplifier, and a Chireix amplifier.

An advantage with this implementation form is that the number different amplifier designs may be used as the main amplifier in the present solution thus providing flexibility.

In an implementation form of a power amplifier according to the first aspect, the second amplifier is a first peak amplifier and the third amplifier is a second peak amplifier.

In an implementation form of a power amplifier according to the first aspect, the first peak amplifier and/or the second peak amplifier is any one of: a single-ended amplifier, a multi-stage Doherty amplifier, a hybrid Doherty amplifier, a CLMA, an inverted CLMA, a LMBA, a distributed LMBA, an envelope tracking amplifier, and a Chireix amplifier.

An advantage with this implementation form is that the number different amplifier designs may be used as the first and second peak amplifiers in the present disclosure thus providing flexibility.

In an implementation form of a power amplifier according to the first aspect, the power amplifier comprises a first signal combiner connected between the output of the first amplifier, the output of the second amplifier and the input port of the circulator.

In an implementation form of a power amplifier according to the first aspect, the power amplifier comprises a fourth amplifier comprising: an input connected to the input block and configured to receive a fourth signal, and an output connected to the isolated port of the circulator and configured to output a fourth amplified signal comprising an amplified version of the fourth signal to the isolated port of the circulator.

In an implementation form of a power amplifier according to the first aspect, the fourth amplifier is a third peak amplifier.

In an implementation form of a power amplifier according to the first aspect, the third peak amplifier is any one of: a single-ended amplifier, a multi-stage Doherty amplifier, a hybrid Doherty amplifier, a CLMA, an inverted CLMA, a LMBA, a distributed LMBA, an envelope tracking amplifier, and a Chireix amplifier.

An advantage with this implementation form is that the number different amplifier designs may be used as the third peak amplifiers in the present solution thus providing flexibility.

In an implementation form of a power amplifier according to the first aspect, the power amplifier comprises a second signal combiner connected between the output of the third amplifier, the output of the fourth amplifier and the isolated port of the circulator.

In an implementation form of a power amplifier according to the first aspect, at least one of the first signal combiner and the second signal combiner is any one of: a microstrip line, a coupler, and a circulator.

In an implementation form of a power amplifier according to the first aspect, the power amplifier comprises an impedance transformer connected between the output of the first amplifier and the output of the second amplifier and configured to match the impedance of the output of the first amplifier and the output of the second amplifier.

In an implementation form of a power amplifier according to the first aspect, the power amplifier is configured to:
turn on the second amplifier and the third amplifier at the same power level.

An advantage with this implementation form is that the load pull ratio of the first amplifier may be kept at the value 1 for improved broadband performance.

In an implementation form of a power amplifier according to the first aspect, the power amplifier is configured to:
turn on the second amplifier and the third amplifier at the same power level and at the same time instance.

In an implementation form of a power amplifier according to the first aspect, the first signal is incident to the first amplifier, the second signal is incident to the second amplifier, and the third signal is incident to the third amplifier.

An advantage with this implementation form is that the performance of the power amplifier can be improved.

In an implementation form of a power amplifier according to the first aspect, the input signal is a radio frequency signal.

An advantage with this implementation form is that the power amplifier according to the first aspect can be used in radio applications such as in base stations.

A second aspect of the present disclosure includes a transmitter device for a communication system, the transmitter device comprising a power amplifier according to any embodiment of the present disclosure.

Further applications and advantages of embodiments of the present disclosure will be apparent from the following detailed description.

### BRIEF DESCRIPTION OF THE DRAWINGS

The appended drawings are intended to clarify and explain different embodiments of the present disclosure, in which:

FIG. 1 shows a power amplifier according to embodiments of the present disclosure;

FIG. 2 shows a power amplifier comprising a main amplifier and two peak amplifiers according to embodiments of the present disclosure;

FIG. 3 to 5 illustrate different number of input channels to the power amplifier according to embodiments of the present disclosure;

FIG. 6 shows a power amplifier comprising a main amplifier and three peak amplifiers according to embodiments of the present disclosure;

FIG. 7 shows a transmitter device for a communication system according to embodiments of the present disclosure; and

FIG. 8 shows a plot of driving current for each amplifier in FIG. 2;

FIG. 9 shows a plot of impedances for each amplifier in FIG. 2; and

FIG. 10 shows a plot of theoretical efficiency against normalized output voltage for the power amplifier in FIG. 2.

### DETAILED DESCRIPTION

A conventional solution for broad bandwidth energy-efficient PA is a multi-stage Doherty amplifier. Multi-stage Doherty is a mature technology, easy to implement, and widely used in radio base stations. The efficiency degradation between back-off power and peak power can be lowered through additional efficiency tents. Multi-stage Doherty solutions are however limited in bandwidth due to load pull ratio (LPR) of main amplifier and off impedance dispersion of the peak amplifiers.

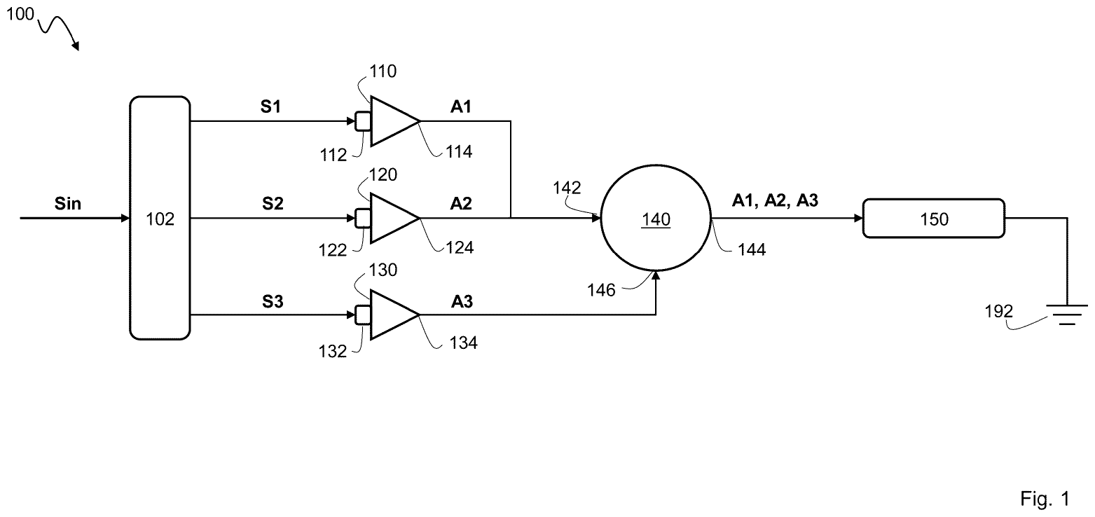

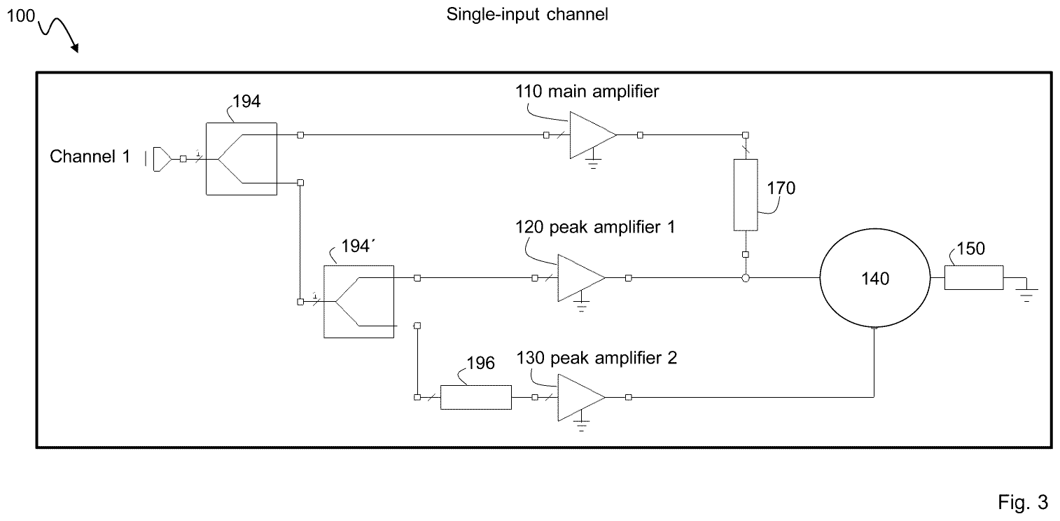

FIG. 1 shows a power amplifier according to embodiments of the present disclosure. The power amplifier 100 herein disclosed comprises an input block 102 configured to receive at least one input signal Sin and provide a first signal S1, a second signal S2 and at a least one third signal S3 based on the input signal Sin. The input signal Sin may be split by the input block 102 to provide the first signal S1, the second signal S2 and the third signal S3. The input block 102 may comprise one or more inputs and one or more outputs. The input block 102 may also comprise one or more splitters and one or more combiners for splitting respectively combining signals. In embodiments, the input signal Sin may comprise of two or more input signals which will be described more in detail with reference to FIG. 3 to 5.

The power amplifier 100 further comprises a first amplifier 110 which comprises an input 112 that is connected to the input block 102 and configured to receive the first signal S1. The first amplifier 110 further comprises an output 114 configured to output a first amplified signal A1 comprising an amplified version of the first signal S1. Hence, the first amplified signal A1 may be understood as the first signal S1 amplified by the first amplifier 110.

The power amplifier 100 further comprises a second amplifier 120 which comprises an input 122 that is connected to the input block 102 and configured to receive the second signal S2. The second amplifier 120 further comprises an output 124 configured to output a second amplified signal A2 comprising an amplified version of the second signal S2. Hence, the second amplified signal A2 may be understood as the second signal S2 amplified by the second amplifier 120.

The power amplifier 100 further comprises a third amplifier 130 which comprises an input 132 that is connected to the input block 102 and configured to receive the third signal S3. The third amplifier 130 further comprises an output 134 configured to output a third amplified signal A3 comprising an amplified version of the third signal S3. Hence, the third amplified signal A3 may be understood as the third signal S3 amplified by the third amplifier 130.

The power amplifier 100 also comprises a circulator 140 which is connected to the outputs of the amplifiers. The circulator 140 comprises an input port 142 connected to the output 114 of the first amplifier 110 and the output 124 of the second amplifier 120. The input port 142 is configured to receive the first amplified signal A1 and the second amplified signal A2 and provide the first amplified signal A1 and the second amplified signal A2 to a load 150 via an output port 144 of the circulator 140. The circulator 140 also comprises an isolated port 146 connected to the output 134 of the third amplifier 130. The isolated port 146 is configured to receive the third amplified signal A3 and provide the third amplified signal A3 to the load 150 via the output port 144 of the circulator 140. Thus, a signal at the isolated port 146 of the circulator 140 bypasses the input port 142 and is outputted at the output port 144 of the circulator 140. The circulator 140 may be configured to operate in clock-wise direction or anti-clock-wise direction depending on the application.

The load 150 may be any suitable type of load. For example, if the power amplifier 100 is connected to a diplexer the load 150 will be the diplexer, if the power amplifier 100 is connected to an antenna the load 150 will be the antenna, if the power amplifier 100 is connected to an attenuator the load 150 will be the attenuator, and so on. The load 150 is impedance matched to the output of the circulator 140 for high performance and is connected to a reference ground 192 of the power amplifier 100. The reference ground may be a virtual ground or an earth ground.

It may be noted that in embodiments of the present disclosure, the first signal S1 is incident to the first amplifier 110, the second signal S2 is incident to the second amplifier 120 and the third signal S3 is incident to the third amplifier 130. This means that the amplitude and phase of the first signal S1, the second signal S2 and the third signal S3 can be designed separately for achieving high performance.

In operation the power amplifier 100 is configured to turn on the second amplifier 120 and the third amplifier 130 at the same power level. More specifically, the power amplifier 100 is configured to turn on the second amplifier 120 and the third amplifier 130 at the same power level and at the same time instance in embodiments of the present disclosure. This means that the LPR of the first amplifier 110 can be kept to 1 because when the second amplifier 120 is turned on, the impedance of the first amplifier 110 will decrease, and when the third amplifier 130 is turned on, the impedance of the first amplifier 110 will increase. Thus, if we want to ensure that the LPR of first amplifier 110 is kept at 1, the second 120 and third 130 amplifiers should be turned on at the same power level. The different amplifiers, devices and components of the power amplifier 100 may be controlled by one or more control devices or control arrangements. The control device or control arrangement may be any suitable devices and arrangements and may comprise hardware and/or software. The amplifiers, devices and components may be connected to the control devices or control arrangements via control lines so that the control devices or control arrangements can control the amplifiers, devices and components. Thus, the control devices or control arrangements may be configured to turn on and turn off the amplifiers.

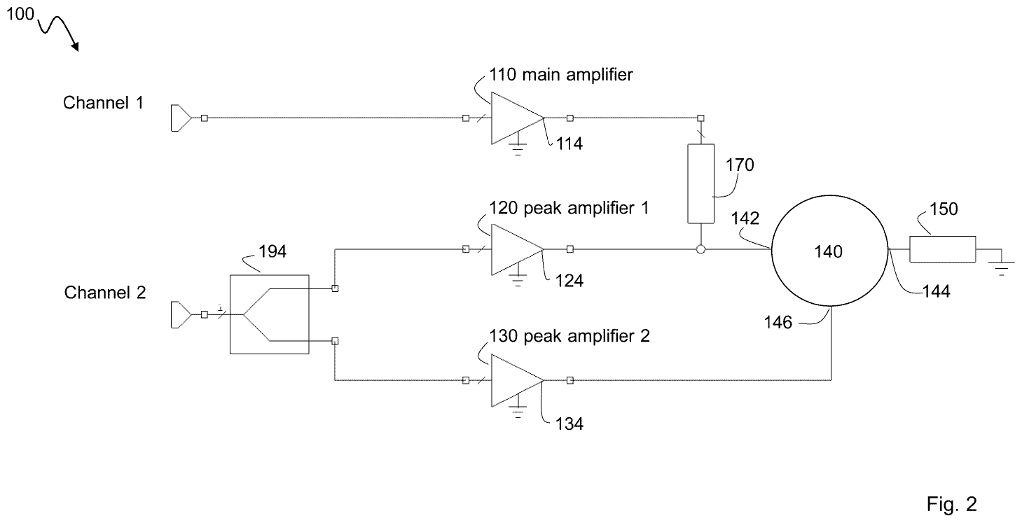

FIG. 2 shows a power amplifier 100 comprising a main amplifier and two peak amplifiers according to embodiments of the present disclosure. Thus, according to these embodiments, the first amplifier 110 comprises a main amplifier while the second amplifier 120 is a first peak amplifier and the third amplifier 130 is a second peak amplifier as shown in FIG. 2. In general, a main amplifier can operate in all power ranges while a peak amplifier only operates from its turn-on power to a peak power level. The main amplifier can achieve high efficiency in the low power level, and below the low power level the load impedance of the main amplifier is constant. Over the low power level, the two peak amplifiers are turned on simultaneously which make it possible for the load impedance of the main amplifier to be constant.

According to the direction of the circulator 140, the signal from the main amplifier 110 will first go to the input port of circulator 140 and then directly to the output port of the circulator 140, and the off state impedance of the second peak amplifier 130 will not introduce insertion loss to the main amplifier 110. Thus, the insertion loss of the power amplifier 100 may be held small.

Different amplifier designs may be used for the main and peak amplifiers employed in the present power amplifier 100. Thus, the main amplifier and the peak amplifiers may be any one of: a single-ended amplifier, a multi-stage Doherty amplifier, a hybrid Doherty amplifier, a Circulator Load Modulated Amplifier (CLMA), an inverted CLMA, a Load Modulated Balanced Amplifier (LMBA), a distributed LMBA, an envelope tracking amplifier, and a Chireix amplifier.

It is also noted from FIG. 2 that the present power amplifier 100 may also comprise an impedance transformer 170 which is connected between the output 114 of the first amplifier 110 and the output 124 of the second amplifier 120. The impedance transformer 170 is configured to match the impedance of the output 114 of the first amplifier 110 and the output 124 of the second amplifier 120. In some power amplifier architectures, an impedance transformer 170 may be needed to realize impedance inversion so that the power amplifier can work properly. The function of impedance transformer is impedance inversion, and the theoretical electric length is quarter wavelength. For instance, assume that the input port impedance of the circulator is 25 ohm and the characteristics impedance of impedance transformer 170 is 50 ohm. When the second amplifier 120 is in its on state, and assuming that the impedance of the output 124 of the second amplifier 120 is 50 ohm, then the output of impedance transformer 170 is 50 ohm. Hence, the impedance of the output 114 of the first amplifier 110 is 50\hat{ }2/50=50 ohm. When the second amplifier is in its off state, the impedance of output 124 of the second amplifier 120 is infinite, then the output of the impedance transformer 170 is 25 ohm, and the impedance of the output 114 of the first amplifier 110 is 50\hat{ }2/25=100 ohm. This is so called load modulation. For 50 ohm and 100 ohm, the first power amplifier 110 can realize high performance, and this is the mechanism of impedance modulated power amplifiers.

Moreover, the input of the power amplifier 100 comprises of two different channels, i.e., a first channel 1 and a second channel 2 in this embodiment. The first channel is fed to the input of the main amplifier 110 for amplification. The second channel is first split in a splitter 194 so that the second channel can be fed to both the input of the first peak amplifier 120 and the input of the second peak amplifier 130 for amplification. A channel herein may be understood as an input signal Sin previously described and may mean a radio frequency signal channel connected to the input port(s) of the power amplifier 100. Usually, the power level from a channel is small. By adjusting the baseband signal, the amplitude and phase of the radio frequency signal from the one or more channels can be changed.

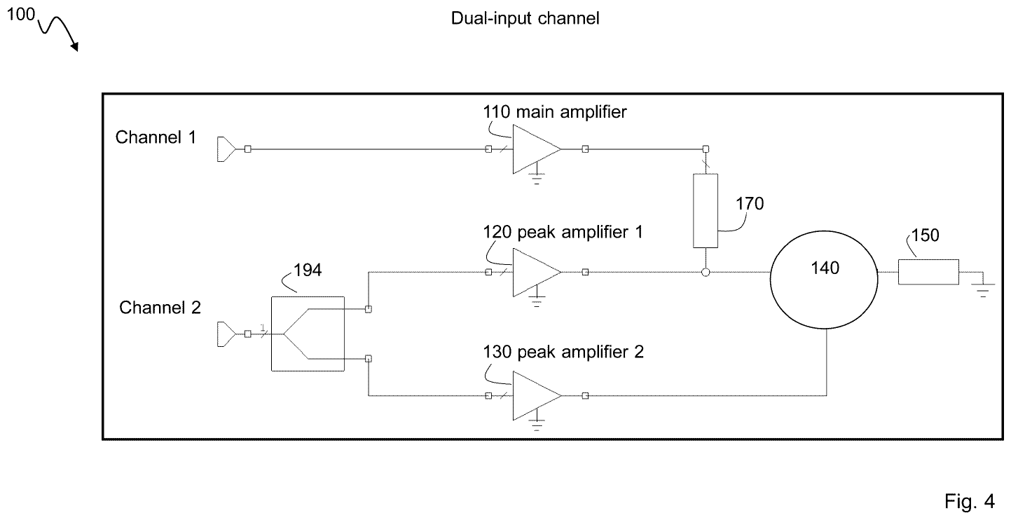

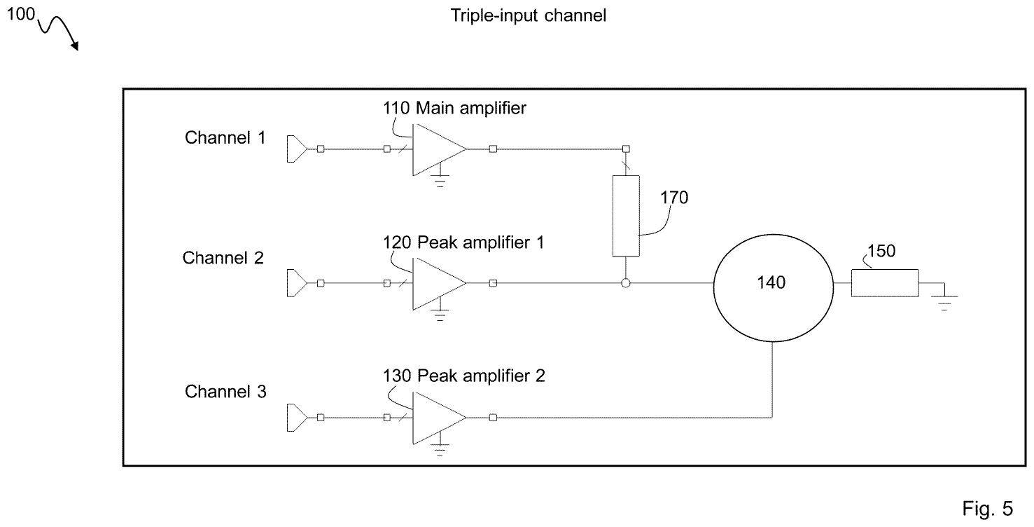

FIGS. 3 to 5 illustrate examples of different number of input channels provided to the power amplifier 100 according to embodiments of the present disclosure. More specifically, FIG. 3 illustrates the case with a single input channel, FIG. 4 the case with dual input channels, and FIG. 5 the case with triple input channels. Embodiments of the present disclosure are however not limited to these numbers of input channels and it is realized that the present power amplifier design allows an endless number of different combinations to achieve the objectives stated herein.

In FIG. 3 a single channel is provided. The first channel 1 is split in a first splitter 194 into two split signals. The first split signal is fed to the main amplifier 110 for amplification. The second split signal is fed to a second splitter 194′ which splits the second split signal into third and fourth splits signals. The third split signal is fed to the first peak amplifier 120 for amplification. The fourth split signal is fed to the second peak amplifier 130 for amplification via a phase alignment 196 to align the phase of the signal from the second splitter 194′.

In FIG. 4 two separate channels are provided. The first channel is fed to the main amplifier 110 for amplification. The second channel on the other hand is split into first and second split signals in a splitter 194. The first split signal is fed to the first peak amplifier 120 for amplification while the second split signal is fed to the second peak amplifier 130 for amplification.

In FIG. 5 three channels are provided. Thus, each channel is fed to its respective amplifier without splitting. Thus, the first channel is fed to the main amplifier 110 for amplification, the second channel is fed to the first peak amplifier 120 for amplification, and the third channel is fed to the second peak amplifier 130 for amplification.

From the above it may be realized that any number of input channels may be provided which are matched with suitable number of splitters and main and peak amplifiers so as to amplify the input channels according to the herein disclosed power amplification embodiments.

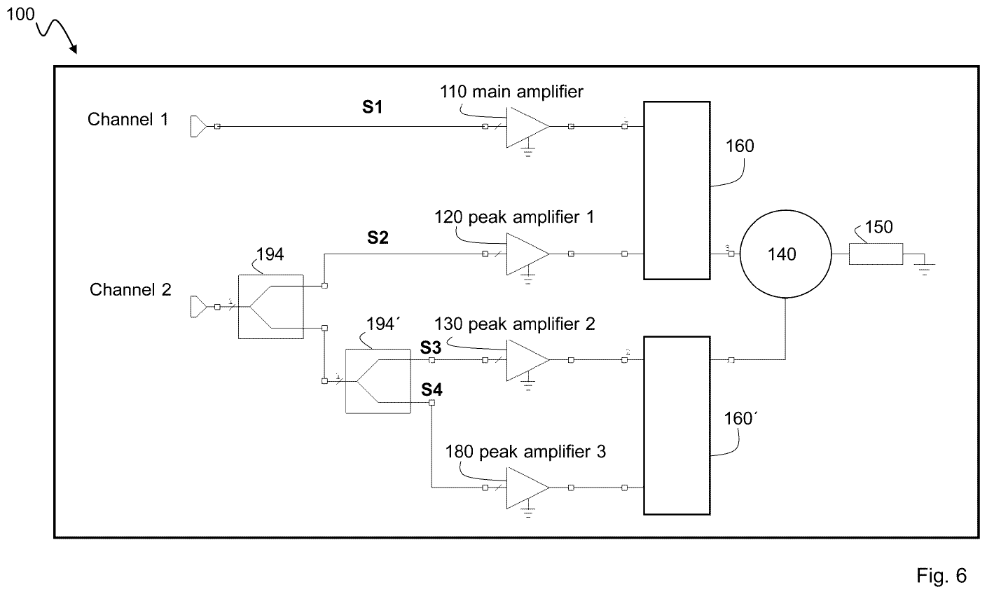

FIG. 6 shows a power amplifier which comprises a main amplifier and three peak amplifiers according to embodiments of the present disclosure. Hence, the power amplifier 100 comprises a fourth amplifier 180 comprising an input 182 connected to the input block 102 and configured to receive a fourth signal S4. The fourth amplifier 180 also comprises an output 184 connected to the isolated port 146 of the circulator 140 and configured to output a fourth amplified signal A4 comprising an amplified version of the fourth signal S4 to the isolated port 146 of the circulator 140. As also shown in FIG. 6 the fourth amplifier 180 may be a third peak amplifier. In embodiments of the present disclosure, the first 120 and second 130 peak amplifiers are turned on at the same power level while the third peak amplifier 180 is turned on at the power level that is higher than the power level for the first and second peak amplifiers. It is realized that any number of amplifiers may be employed for providing the embodiments of the present disclosure.

As for the main 100, first 120 and second 130 peak amplifiers, the third peak amplifier 180 may be any one of: a single-ended amplifier, a multi-stage Doherty amplifier, a hybrid Doherty amplifier, a CLMA, an inverted CLMA, a LMBA, a distributed LMBA, an envelope tracking amplifier, and a Chireix amplifier.

From FIG. 6 is may also be derived that the present power amplifier 100 comprises one or more signal combiners which function is to combine signals from different amplifiers. Further, the combiners may also act as a load modulation function so that the power amplifier can achieve high performance. FIG. 6 shows a first signal combiner 160 connected between the output 114 of the first amplifier 110, the output 124 of the second amplifier 120 and the input port 142 of the circulator 140. The shown power amplifier 100 also comprises a second signal combiner 160′ connected between the output 314 of the third amplifier 130, the output 184 of the fourth amplifier 180 and the isolated port 146 of the circulator 140.

Since the first 110 and second 120 amplifiers are both connected to the input port of the circulator 140, a first combiner 160 is connected between the outputs of the main amplifier 110 and the first peak amplifier 120. Because the second 130 and third 140 peak amplifiers are both connected to the isolated port of the circulator 140, a second combiner 160′ is connected between the outputs of the second 130 and third 140 peak amplifiers. Different combiners and combiner configurations make it possible for different power amplifier architectures. The signal combiners 160, 160′ may be of different types and may be any one of: a microstrip line, a coupler, and a circulator.

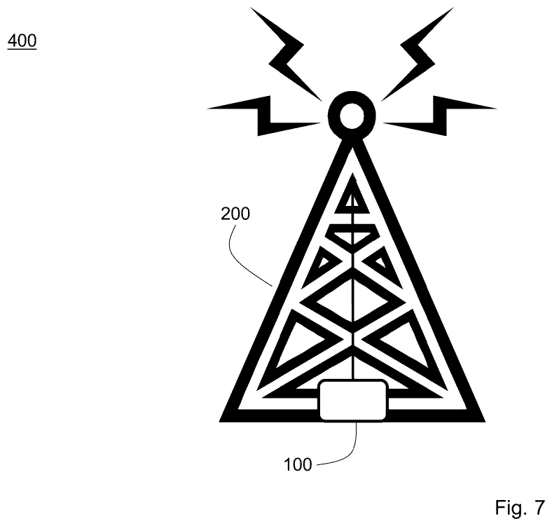

FIG. 7 shows a transmitter device 200 according to embodiments of the present disclosure. The transmitter device 200 herein disclosed is configured for transmitting in a wireless communication system 400. Thus, the transmitter device 200 comprises a power amplifier 100 according to embodiments of the present disclosure. The power amplifier 100 may be part of the radio transmission chain of the transmitter device 200. The exemplified transmitter device 200 in FIG. 7 is a base station but is not limited thereto and may be any transmitter device configured for transmission in a wireless communication system.

The wireless communication system 400 may be any wireless communication system such as 3GPP long term evolution (LTE) or fifth generation (5G) new radio (NR). Therefore, it is noted that the input signal Sin for amplification in the power amplifier 100 is a radio frequency signal in such communication systems. The radio frequency signal may be a broadband communication signal.

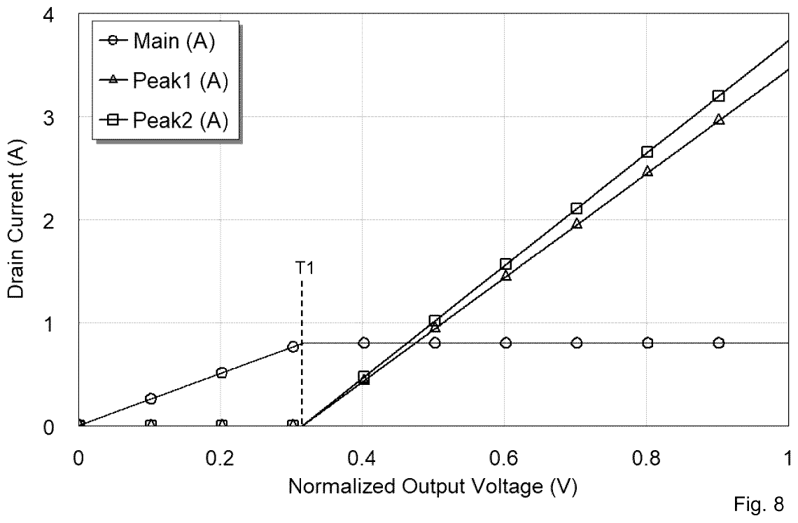

FIG. 8 shows a plot of the drain current against normalized voltage of the output signal for each amplifier in FIG. 2 according to an example of the present disclosure. Assuming that the first peak amplifier and second peak amplifier are turned on together at the same normalized voltage T1, when the normalized voltage of the output signal is less than T1, the drain current of the main amplifier increases which also means that the output signal voltage increases. When the normalized voltage of output signal reaches to T1, the drain current of the first peak amplifier and the second peak amplifier increases from 0, and the drain current of the main amplifier stops increasing and remains constant.

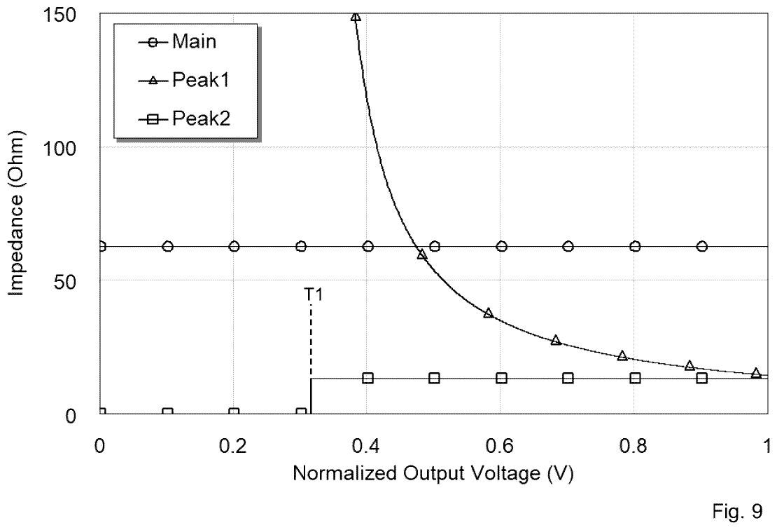

FIG. 9 shows a plot of the impedance against the normalized voltage of the output signal for each amplifier in FIG. 2 according to an example of the present disclosure. Before and after output signal voltage T1, the impedance of the main amplifier is the same, i.e., the LPR of the main amplifier is kept to value 1.

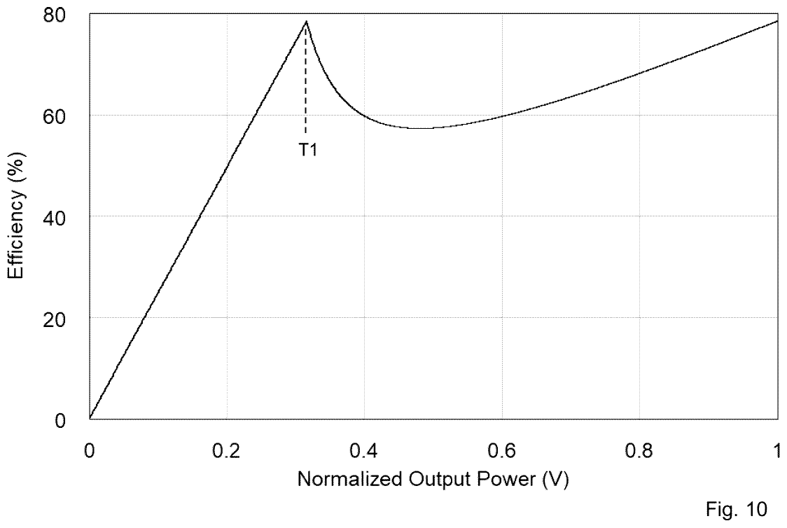

FIG. 10 shows a plot of the theoretical efficiency against normalized output voltage for the power amplifier in FIG. 2 according to an example of the present disclosure. Because the first peak amplifier and the second peak amplifier are turned on at the same power level, the efficiency saturation occurs only at the two normalized output voltages, i.e., at value T1 and 1.

Finally, it should be understood that the invention is not limited to the embodiments described above, but also relates to and incorporates all embodiments within the scope of the appended independent claims.

What is claimed is:

1. A power amplifier comprising:
an input block configured to receive at least one input signal and provide a first signal, a second signal and at least one third signal based on the input signal;
a first amplifier comprising: an input connected to the input block and configured to receive the first signal, and an output configured to output a first amplified signal comprising an amplified version of the first signal;
a second amplifier comprising: an input connected to the input block and configured to receive the second signal, and an output configured to output a second amplified signal comprising an amplified version of the second signal;
a third amplifier comprising: an input connected to the input block and configured to receive the third signal, and an output configured to output a third amplified signal comprising an amplified version of the third signal; and
a circulator comprising: an input port connected to the output of the first amplifier and the output of the second amplifier and configured to receive the first amplified signal and the second amplified signal and provide the first amplified signal and the second amplified signal to a load via an output port of the circulator, and an isolated port connected to the output of the third amplifier and configured to receive the third amplified signal and provide the third amplified signal to the load via the output port of the circulator.

2. The power amplifier according to claim 1, wherein the first amplifier comprises a main amplifier.

3. The power amplifier according to claim 2, wherein the main amplifier is at least one of: a single-ended amplifier, a multi-stage Doherty amplifier, a hybrid Doherty amplifier, a circulator load modulated amplifier (CLMA), an inverted CLMA, a load-modulated balanced amplifier (LMBA), a distributed LMBA, an envelope tracking amplifier, and a Chireix amplifier.

4. The power amplifier according to claim 1, wherein the second amplifier is a first peak amplifier and the third amplifier is a second peak amplifier.

5. The power amplifier according to claim 4, wherein the first peak amplifier and/or the second peak amplifier is at least one of: a single-ended amplifier, a multi-stage Doherty amplifier, a hybrid Doherty amplifier, a circulator load modulated amplifier (CLMA), an inverted CLMA, a load-modulated balanced amplifier (LMBA), a distributed LMBA, an envelope tracking amplifier, and a Chireix amplifier.

6. The power amplifier according to claim 1, wherein the power amplifier further comprises a first signal combiner connected between the output of the first amplifier, the output of the second amplifier, and the input port of the circulator.

7. The power amplifier according to claim 6, wherein the power amplifier further comprises a fourth amplifier comprising: an input connected to the input block and configured to receive a fourth signal, and an output connected to the isolated port of the circulator and configured to output a fourth amplified signal comprising an amplified version of the fourth signal to the isolated port of the circulator.

8. The power amplifier according to claim 7, wherein the fourth amplifier is a third peak amplifier.

9. The power amplifier according to claim 8, wherein the third peak amplifier is at least one of: a single-ended amplifier, a multi-stage Doherty amplifier, a hybrid Doherty amplifier, a circulator load modulated amplifier (CLMA), an inverted CLMA, a load-modulated balanced amplifier (LMBA), a distributed LMBA, an envelope tracking amplifier, and a Chireix amplifier.

10. The power amplifier according to claim 7, wherein the power amplifier further comprises a second signal combiner connected between the output of the third amplifier, the output of the fourth amplifier and the isolated port of the circulator.

11. The power amplifier according to claim 7, wherein at least one of the first signal combiner and the second signal combiner is at least one of: a microstrip line, a coupler, and a circulator.

12. The power amplifier according to claim 1, wherein the power amplifier further comprises an impedance transformer connected between the output of the first amplifier and the output of the second amplifier and configured to match the impedance of the output of the first amplifier and the output of the second amplifier.

13. The power amplifier according to claim 1, wherein the power amplifier is configured to:
turn on the second amplifier and the third amplifier at a same power level.

14. The power amplifier according to claim 13, wherein the power amplifier is further configured to:
turn on the second amplifier and the third amplifier at the same power level and at a same time instance.

15. The power amplifier according to claim 1, wherein the first signal is incident to the first amplifier, the second signal is incident to the second amplifier, and the third signal is incident to the third amplifier.

16. The power amplifier according to claim 1, wherein the at least one input signal is a radio frequency signal.

17. A transmitter device for a communication system, the transmitter device comprising a power amplifier according to claim 1.
